(19) United States
(12) Patent Application Publication
(10) Pub. No.: US 2016/0258600 A1
(43) Pub. Date: Sep. 8, 2016

(54) BULB WITH ADJUSTABLE DISPERSAL OF LIGHT

(71) Applicants: Arun K. JAIN, Pune (IN); Vibhor JAIN, Pune (IN)

(72) Inventors: Arun K. JAIN, Pune (IN); Vibhor JAIN, Pune (IN)

(21) Appl. No.: 14/876,598

(22) Filed: Oct. 6, 2015

(30) Foreign Application Priority Data
Mar. 3, 2015 (IN) 687/MUM/2015

(51) Int. Cl. F21V 14/02; F21V 23/00; H05K 1/18; F21K 99/00; H05K 1/05

(52) U.S. Cl. CPC F21V 14/02; F21K 9/135; H05K 1/05; H05K 1/181; F21V 23/005; F21Y 2101/02; F21Y 2105/003

(57) ABSTRACT

The present invention relates to a light emitting diode bulb. More particularly, the present invention relates to a light emitting diode bulb with adjustable scattering of light. The said bulb comprising a base, an envelope coupled to the base, a mounting assembly, a moving mechanism and a plurality of light emitting diodes linked with the moving mechanism. The said moving mechanism comprises a shaft and a connector assembly. A user may make an adjustment in the moving mechanism that allows the user to adjust the beam angle of the light from the bulb, as per the requirement.

### FIELD OF THE INVENTION

The present invention relates to an adjustable light bulb. More particularly, the present invention relates to a light emitting diode (LED) bulb with adjustable dispersal of light, controlled by a user.

### BACKGROUND OF THE INVENTION

Discovery of electricity opened new channels for modernization for human race. Along with the discovery of electricity came into existence lamps, wherein such lamps replaced the conventional means of illumination and were completely dependent on electricity. Electric lamps further kept on evolving with ages and till date pose a challenge for the technicians to come up with more advance and power saving technologies in lamps. The basic conventional lamps used tungsten filament for illumination and gave yellow light. Then came into existence tube lights that used inert gases for illumination using electricity, wherein the light emitting diodes (LED) are the most recent advancement in this industry also commonly known as LED lamp/bulb.

Undoubtedly LED lamps are energy efficient, have high life and are rapidly becoming the first choice of the user. However in the conventional technology, the position of LED lamps is fixed and hence the light distribution is also fixed. That means if the user wants to change the direction/distribution of light then, the entire fixture needs to be rotated/moved. Further the conventional technology fails to provide any solution to the problem where the light of lamps may be concentrated to only one particular area and restricting it to reach unwanted areas. However, the conventional lamps may be manufactured as narrow beam lamp, wide beam lamp or even distribution lamp (light in all direction). But in such cases the lamp is fixed and the light is evenly distributed however there is no provision by which direction of light from the bulb may be controlled.

Thus, there exist a need of LED lamp that may be adjusted by the user as per the requirement. Moreover, there exist a need of LED lamp in which the direction of light may be adjusted as per the user requirement and hence saving energy by avoiding it to reach to unwanted areas.

### SUMMARY OF THE INVENTION

In an aspect, the present invention relates to a light bulb with adjustable dispersal of light. The said bulb comprises a base, an envelope coupled to the base, and a mounting assembly placed inside the envelope. The said mounting assembly includes a top surface and a bottom surface, wherein the bottom surface may remain fixed to the base. The said bulb further comprises a plurality of plate radially engaged over the top surface of the mounting assembly via hinge mechanism, using a plurality of hook. In an embodiment, these plurality of hook may include pinion formed around there outer periphery. The bulb further comprises a plurality of light emitting diode (LED) mounted on top surface of the plurality of plates and a connector arranged within the mounting assembly. The connector may be arranged in a manner so that it extends longitudinally from the top surface to the bottom surface of the mounting assembly. The said connector further includes a plurality of rack radially attached such that each of the rack meshes with the respective pinion of the hook. Further, proximal end of the connector may be engaged with a cylindrical shaft, having spiral grooves. The connector may be attached to the shaft in a way, such that the rotation of shaft allows the connector to move in one of upward or downward direction. The movement of connector in one of upward or downward direction allows the pinion to move over the rack and thus actuating the movement of the plurality of light emitting diodes around their axis, via hinge mechanism. The said movement of light emitting diodes allows a user to adjust beam angle of light.

In another aspect, the proximal end of the connector may be engaged within the spiral grooves of the cylindrical shaft such that the rotation of shaft provides linear motion to the connector.

In yet another aspect, the cylindrical shaft may be rotated via the envelope.

In still another aspect, the cylindrical shaft may be rotated via an external knob, placed at the top of the envelope.

In yet another aspect, the cylindrical shaft may be attached with the envelope, via a groove formed inside the envelope.

In still another aspect, the cylindrical shaft may be rotated using a circular disc being attached to the shaft, wherein the disc may be mounted over the top surface of the envelope.

In yet another aspect, the rotation of shaft allows the user to move the plurality of light emitting diodes simultaneously in one direction to adjust the beam angle of the light from the bulb.

In still another aspect, the movement of plurality of light emitting diodes may be performed remotely by a handheld device comprising one of wifi, Bluetooth and like functions.

In yet another aspect, the present invention relates to a light bulb with adjustable dispersal of light. The said bulb comprises a base, an envelope coupled to the base and a mounting assembly placed inside the envelope. The mounting assembly further comprises a top surface and a bottom surface, wherein the bottom surface may be fixed to the base. The said bulb further comprise a plurality of metal core printed circuit board (MCPCB), mounted radially over the top surface of the mounting assembly. The metal core printed circuit board (MCPCB) may be configured to comprise a plurality of light emitting diodes placed equidistance to each other. Further, a control circuit may be secured within the base, to regulate the plurality of light emitting diodes in order to adjust beam angle of light.

In still another aspect, the mounting assembly comprises plurality of pre-shaped metal core printed circuit board mounted radially over the top surface.

In yet another aspect, the plurality of metal core printed circuit board may comprise equal number of light emitting diode arranged equidistance from each other.

In still another aspect, the control circuit may be configured to regulate at least one of switching and brightness of light emitting diodes.

In yet another aspect, the control circuit may be attached to an external knob, wherein the knob may be configured to regulate the control circuit.

In yet another aspect, the switching and brightness of light emitting diode may be controlled remotely by a handheld device comprising one of wifi, Bluetooth and like functions.

In still another aspect, the control circuit may be configured to regulate at least one of the switching and brightness of the plurality of light emitting diode of at least one of the metal core printed circuit board.

In yet another aspect, the present invention relates to a method for adjusting the scattering of light from the bulb. The said method comprising steps of, rotating a knob, manually to move the plurality light emitting diodes around their axis, so that the beam angle of the light from the bulb may be adjusted.

In still another aspect, the beam angle may be adjusted by controlling at least one of switching and brightness of light emitting diodes in the bulb.

In yet another aspect, the movement of light emitting diodes may be controlled by a handheld device comprising one of wifi, Bluetooth and like functions.

### Object of the Invention

The main of object, of the present invention is to provide a light emitting diode bulb with adjustable dispersal of light.

Another object, of the present invention is provide a user adjustable light emitting diode bulb.

Still another object, of the present invention is to provide a light emitting diode bulb, with variable beam angle of light.

Yet another object of the present invention is to provide a light bulb with an external knob for the user to adjust the dispersal of light, wherein the knob may be placed at distinct locations of the bulb.

Still another object of the invention is to provide a low wattage, energy efficient light bulb.

### BRIEF DESCRIPTION OF THE DRAWINGS

The features of the present invention are set forth with particularity in the appended claims. The invention itself, together with further features and attended advantages, will become apparent from consideration of the following detailed description, taken in conjunction with the accompanying drawings. One or more embodiments of the present invention are now described, by way of example only, with reference to the accompanied drawings wherein like reference numerals represent like elements and in which:

FIG. 1(a) is a perspective view of a light emitting diode bulb, with adjustable dispersal of light.

FIG. 1(b) shows perspective view of a mounting assembly of the bulb.

FIG. 2(a) is a perspective view disclosing mounting assembly in combination with moving mechanism and plurality of light emitting diodes.

FIG. 2(b) is side view of the connector assembly.

FIG. 3 represents a pinion of an LED plate meshed with a gear of moving mechanism.

FIG. 4(a) is a cross-sectional view of the light emitting diode bulb.

FIG. 4(b) discloses top view of the light emitting diode bulb, having circular disc arranged at center of the envelope.

FIG. 5(a) is a cross-sectional view of light emitting diode bulb comprising metal core printed circuit board (MCPCB).

FIG. 5(b) is side view of the metal core printed circuit board (MCPCB) comprising plurality of light emitting diode (LED).

FIG. 6(a) and FIG. 6(b) represents light emitting diode bulb showing dispersal of light at different beam angles and/or in different directions.

### DETAILED DESCRIPTION

While the invention is susceptible to various modifications and alternative forms, specific embodiment thereof has been shown by way of example in the drawings and will be described in detail below. It should be understood, however that it is not intended to limit the invention to the particular forms disclosed, but on the contrary, the invention is to cover all modifications, equivalents, and alternative falling within the spirit and the scope of the invention as defined by the appended claims.

Before describing in detail embodiments it may be observed that the novelty and inventive step that are in accordance with the present invention reside in the light bulb with user adjustable dispersal of light accordingly, the drawings are showing only those specific details that are pertinent to understanding the embodiments of the present invention so as not to obscure the disclosure with details that will be readily apparent to those of ordinary skill in the art having benefit of the description herein.

The terms “comprises”, “comprising”, or any other variations thereof, are intended to cover a non-exclusive inclusion, such that a setup, device that comprises a list of components does not include only those components but may include other components not expressly listed or inherent to such setup or device. In other words, one or more elements in a system or apparatus proceeded by “comprises . . . a” does not, without more constraints, preclude the existence of other elements or additional elements in the system or apparatus.

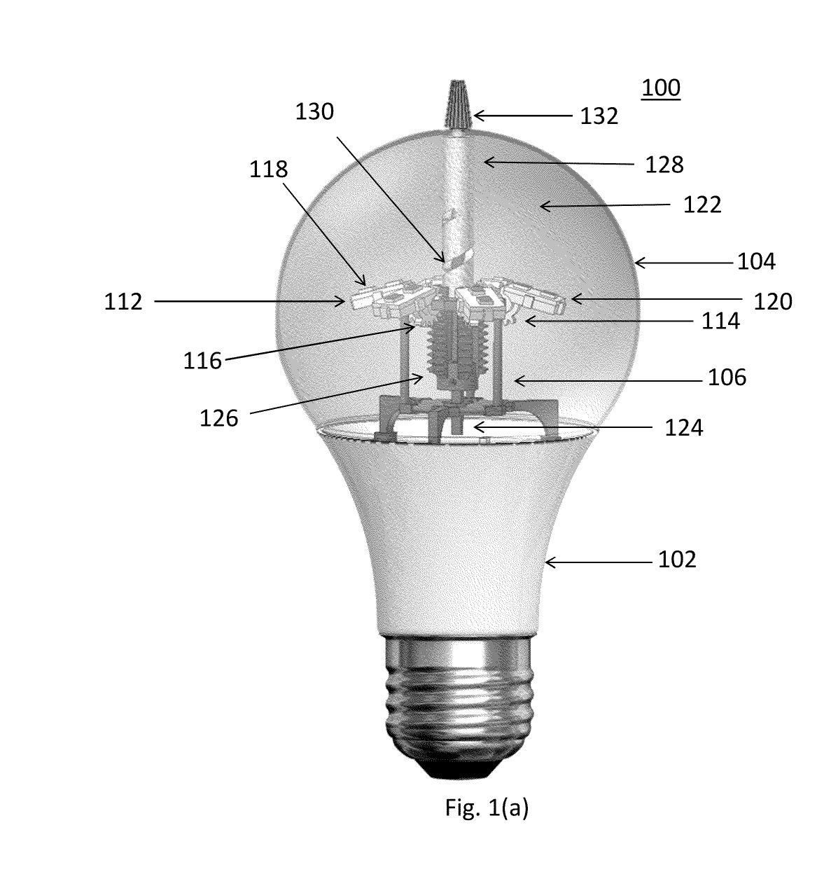

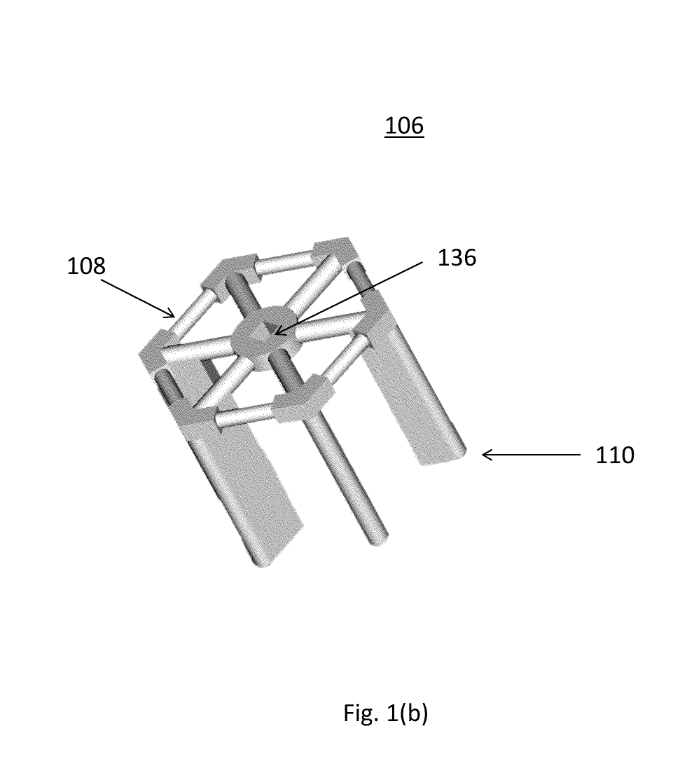

FIG. 1(a) represents front view of a light emitting diode (LED) bulb 100. The said bulb 100 comprises a base 102, an envelope 104 coupled to the base 102. In an example, the envelope 104 of the bulb 100 may be composed of one of glass or polymer and like material which is transparent and suitable for dispersal of light from the bulb 100. The bulb 100 further comprises a mounting assembly 106 placed inside the envelope 104. The mounting assembly 106 includes a top surface 108 and a bottom surface 110, shown clearly in FIG. 1(b). In an embodiment, the bottom surface 110 of the mounting assembly 106 may be fixed to the base of the bulb for support, wherein the top surface 108 of the mounting assembly 106 may be kept free. Specifically, in an embodiment, the top surface 108 may be a hollow surface having one of ring or disc or hexagonal and like structures as shown in FIG. 1(b), to engage a plurality of plates 112. In particular, said plurality of plates 112 may be engaged radially over the top surface 108 via hinge mechanism using a plurality of hooks 114, wherein, each of the said plurality of hook 114 may be configured to include a pinion 116 on its outer periphery. To grip the plurality of hooks 114 on the top surface 108, the mounting assembly 106 may be made out of a strong material. Specifically, the mounting assembly 106 may be made of any lightweight thermal conductive material such as aluminum alloy and like materials. Further, said plates 112 comprise a plurality of light emitting diodes (LED) 118 placed over a top surface 120. In an example, each of the plurality of plates 112 may include equal number of light emitting diodes 118.

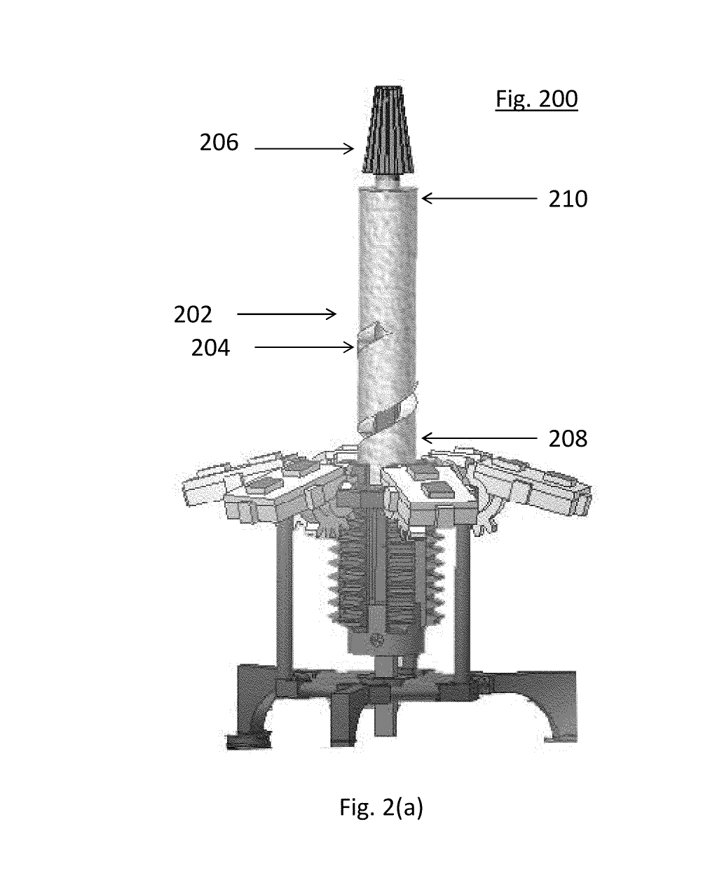

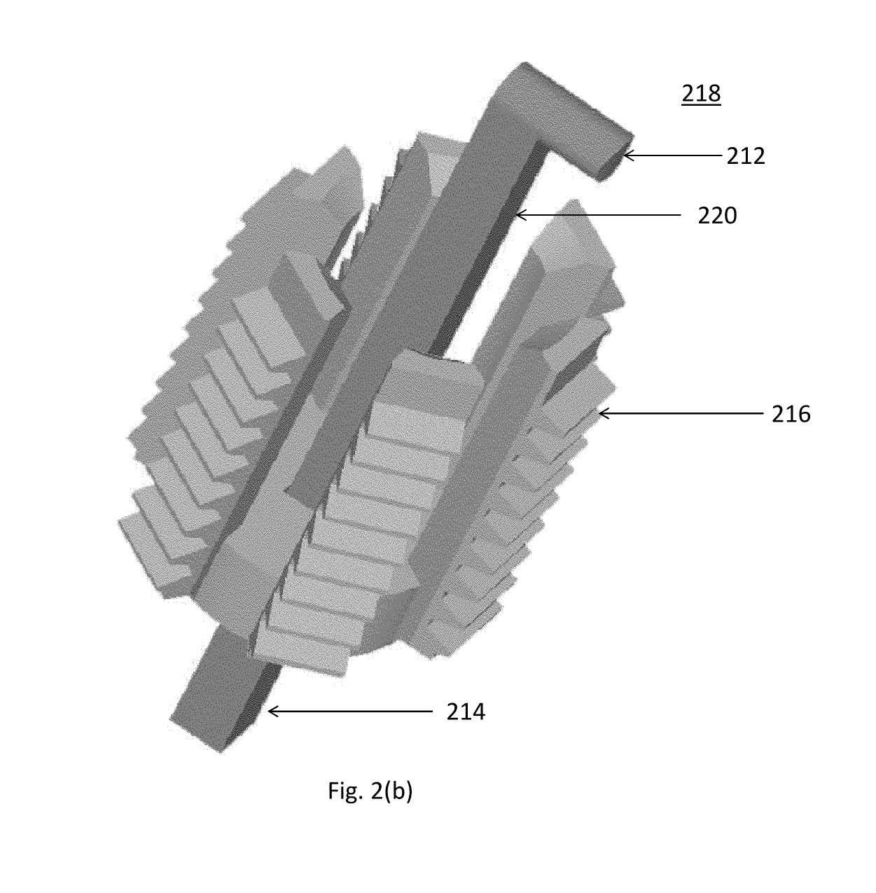

Bulb 100 further comprising a moving mechanism 122, discussed in detail in FIG. 2(a). However, the moving mechanism 122, as shown in FIG. 1(a) further comprising a connector 124, wherein the connector 124 is placed within the mounting assembly 106. The said connector 124 extends longitudinally from the top surface 108 of the mounting assembly 106 to the bottom surface 110 of the mounting assembly 106 through a hole 136, present at the center of the top surface 108 of the mounting assembly 106. Said hole 136 allows smooth movement of moving mechanism 122 within the mounting assembly 106. The connector 124 further includes a pluralities of rack 126 attached radially to its outer body, such that each of the rack 126 meshes with respective pinion 116 of the hook 114. Therefore, in an example, the number of racks 126 in the bulb 100 may be equal to the number of hooks 114 in the bulb 100. More specifically, the bulb 100 comprises equal number of plates 112 and rack 126 attached to the connector 124. In an example, the said connector 124 may include L shaped bend (shown clearly in FIG. 2(b) at proximal end, wherein the said bend may be configured to engage with a cylindrical shaft 128 having spiral groove 130 across its body. The arrangement between the connector 124 and the cylindrical shaft 128 may be such that the rotation of shaft 128 allows the connector 124 to move in one of upward and downward directions. This movement of connector 124 allows meshing of each pinion 116 with the respective rack 126. This in turn actuates the movement of plurality of plates 112 around their axis, via hinge mechanism in order to adjust beam angle of light from the bulb 100.

In an embodiment, the rotation of shaft 128 may be controlled using a knob 132, wherein the knob 132 is mounted at the top of the envelope 104 and is connected to the cylindrical shaft 128. In another embodiment, the rotation of shaft 128 may be controlled using a circular disc (not shown), wherein the circular disc (not shown) may be mounted at the top of the envelope 104. In another embodiment, the rotation of shaft 128 may be controlled via the envelope 104. Specifically in an embodiment, to control the rotation of shaft 128 via envelope 104, the envelope 104 is not fixed with the base 102.

In an embodiment, the terms cylindrical shaft 128 and shaft 128 may be used interchangeably. In another embodiment, the terms bulb 100 and light emitting diode bulb 100 may be used interchangeably.

FIG. 2(a) represents perspective view of moving mechanism 200 in combination with mounting assembly 106 and plurality of light emitting diodes 118, wherein FIG. 2(b) represents perspective view of connector assembly. As shown in FIG. 2(a), the moving mechanism 200 comprises a hollow cylindrical shaft 202 having see-through spiral grooves 204 on its surface. In an embodiment, the grooves 204 may be made on the cylindrical shaft 202 such that they run across the length of the shaft 202, from a distal end 208 to a proximal end 210, in spiral arrangement. In another embodiment, the proximal end 210 of the shaft 202 may remain connected to a knob 206, placed on top surface (not shown), outside the envelope 104. In particular, the knob 206 allows a user (not shown) to control the rotation of the shaft 202 externally. The moving mechanism 200 further includes a connector assembly 218 (as shown in FIG. 2(b)), comprising a connector 220 placed longitudinally within the mounting assembly 106. In an example, the connector 220 may be a thin member having a L shaped bend at proximal end 212, a distal end 214 and a body having a predefined length, between the proximal end 212 and the distal end 214 as shown in FIG. 2 (b). FIG. 2(b) clearly represents structure of the connector assembly 218, wherein, the proximal end 212 is configured to be engaged with the hollow cylindrical shaft 202, via the L shaped bend. In particular, the proximal end 212 of the connector 220 may be engaged within the spiral groove 204 of the hollow cylindrical shaft 202, such that the rotation of the shaft 202 allows the proximal end 212 of the connector 220 to move in one of upward and downward directions inside the spiral groove 204. This upward and downward movement of the proximal end 212 of the connector 220 thus provides linear motion to the connector assembly 218. The said connector 220 further include a plurality of rack 216 attached radially around the body, wherein the said racks 216 may be mounted over the connector 220 body via a circular disc (not shown). Attachment of racks 216 over the circular disc (not shown) ensures proper spacing between the racks 216 and the connector 220. The said space between the racks 216 and connector 220 ensures hassle free movement of the shaft 202 inside the connector assembly 218. In an embodiment, the connector assembly 218 may be made of any light weight thermal conductive material. Specifically in an embodiment, the connector assembly 218 may be made out of lightweight aluminum alloy.

FIG. 2(b), represents side view of the connector assembly 218. Moreover FIG. 2(a) and FIG. 2(b) further assists in understanding how the movement of plurality of light emitting diodes 118 may be controlled via connector assembly 218. As shown in FIG. 2(a) the plurality of plates 112 are attached radially across the top surface 108 of the mounting assembly 106. Plates 112 may be attached to the top surface 108 using a plurality of hook 114, wherein the hooks 114 are configured to include pinion 116 on their outer surface. The arrangement of plates 112 is made such that each of the pinion 116 may mesh with the respective rack 216. Therefore, the bulb 100 may include equal number of racks 216 and plates 112. These plates 112 further include plurality of light emitting diode 118 mounted over the top surface 120 of the plates 112. The arrangement shown in FIG. 2(a) shows that whenever, the knob 206 is rotated, it rotates the shaft 202, this in turn actuates linear movement in the connector assembly 218 and thus causing meshing of rack 216 with the pinion 116. The said meshing between the rack 216 and the pinion 116 finally allows the movement of light emitting diodes 118 in one of upward and downward directions. In an embodiment, the rotation of knob 206 in clockwise direction, allows the connector assembly 218 to move in upward direction. This upward movement of the connector assembly 218 allows pinion 116 of the hook 114 to run over the racks 216 from upward to downward direction, allowing the light emitting diodes 118 to move in downward direction and thus increasing the beam angle of light scattering out of the bulb 100. Similarly, in another embodiment, the rotation of knob 206 in counter clockwise direction, allows the connector assembly 218 to move in downward direction. This downward movement of the connector assembly 218 allows pinion 116 of the hook 114 to run over the racks 216 from downward to upward direction, allowing the light emitting diodes 218 to move in upward direction and thus decreasing the beam angle of light scattering out of the bulb 100.

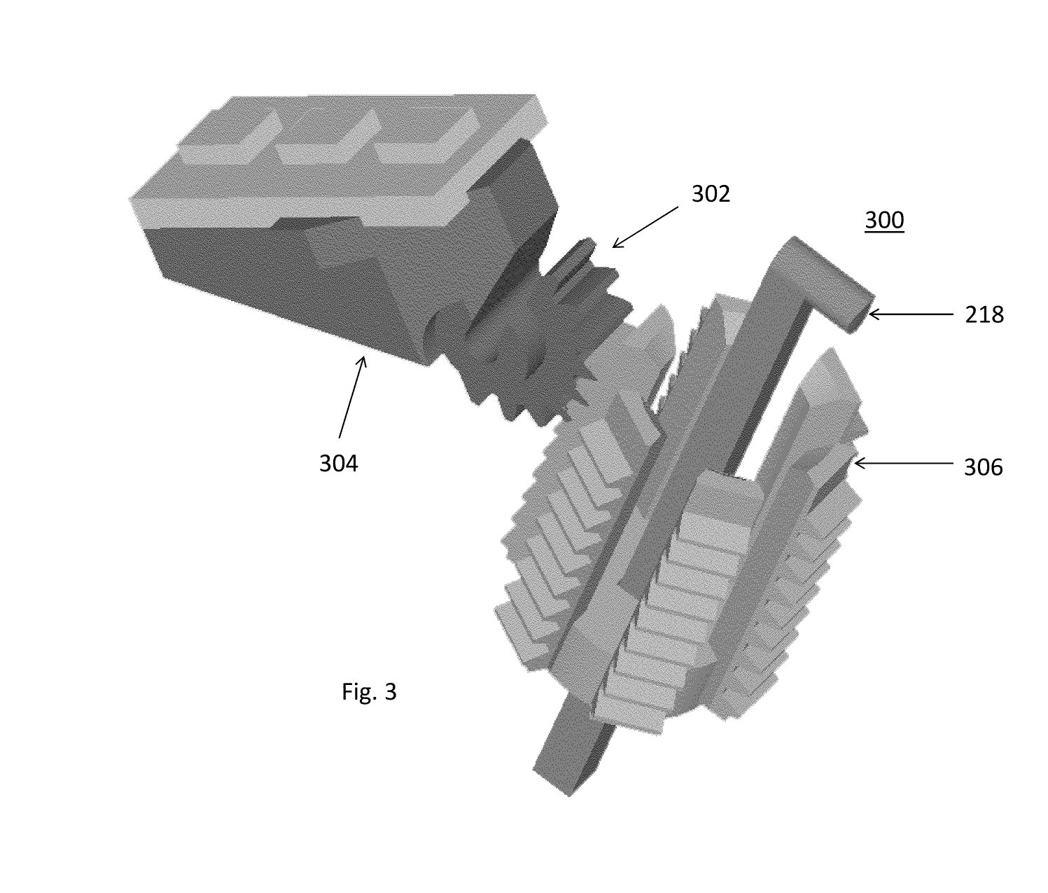

FIG. 3 shows meshing of a pinion 302 of a plate 304 with a rack 306 of the connector assembly 218. FIG. 3 clearly shows meshing and explaining the moving mechanism inside the bulb 100. In an embodiment, the movement of the pinion 302 over the rack 306, from upward to downward direction moves plate 304 in downward direction around its axis. Specifically in an embodiment, the movement of plate 304 allows a plurality of light emitting diodes 308 to move in downward direction, increasing the beam angle of light scattering out of the bulb 100. In another embodiment, the movement of pinion 302 over the rack 306, from downward to upward direction (not shown) moves the plates 304 in upward direction around its axis. Specifically in an embodiment, the movement of plate 304 allows the plurality of light emitting diodes to move in upward direction, reducing the beam angle of light scattering out of the bulb 100. In an example, the plates 304 and pinion 302 may be made of similar material as that of connector assembly 218.

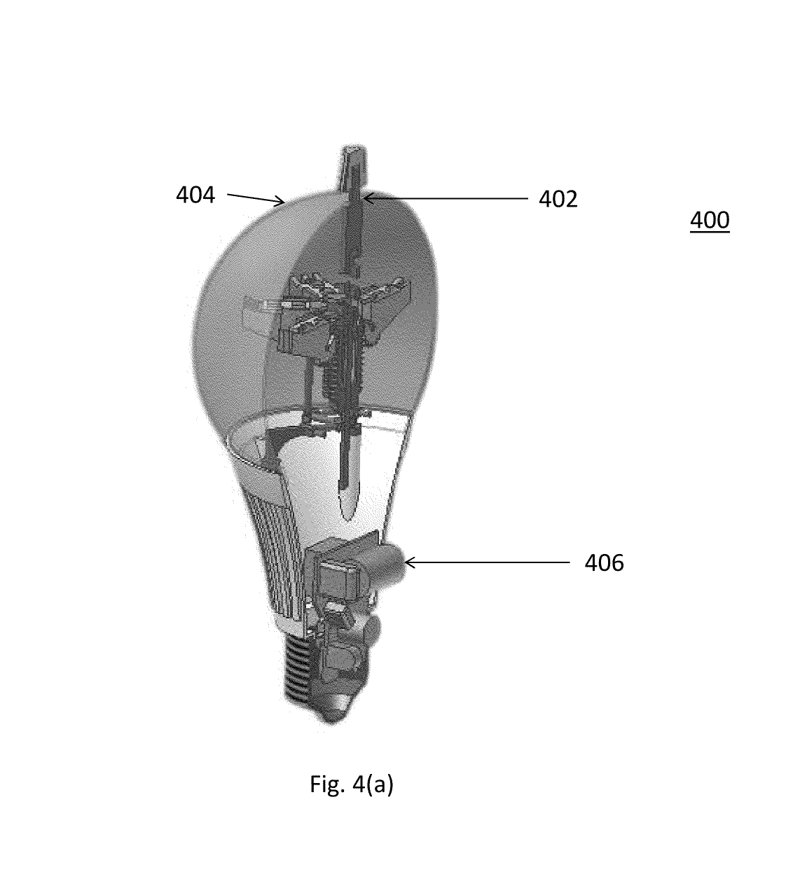

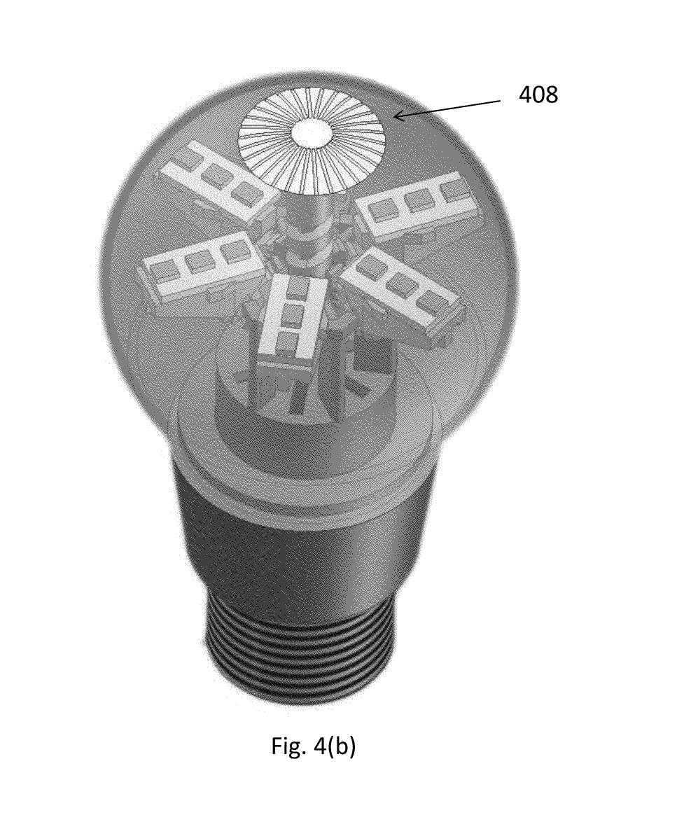

FIG. 4(a) shows cross-sectional view of the bulb 100. FIG. 4(a) clearly shows that the envelope 104 of the bulb 100 includes a hole 402 on its top surface 404. The said hole 402 allows the proximal end 210 of the shaft 202, to be placed outside the envelope 104, wherein the proximal end 210 may be connected to the knob 206. The knob 206 may be configured to allow the user (not shown) to rotate the shaft 202. In another embodiment, as show in FIG. 4(b) the shaft 202 may be rotated using a circular disc 408 mounted over the top surface 404 of the envelope 104. For the shaft 202 to be rotated via the circular disc (not shown), the proximal end 210 of the shaft 202 may be kept inside the envelope 104, being attached to the circular disc for rotation of shaft 202. In another embodiment, the shaft 202 may be rotated using the rotation of the envelope 104. For the shaft 202 to be rotated via the rotation of envelope, the proximal end 210 of the shaft 202 may be engaged within the envelope 104, using a groove (not shown) made inside the envelope 104. Therefore, once the envelope 104 is rotated, it rotates the shaft 202, wherein the envelope 104 and base 102 are not fixed with each other. FIG. 4(a) further shows electronic circuitry 406 placed at the bottom of the base. The said electronic circuitry 406 may be connected to the plurality of light emitting diode 118, through a set of wires (not shown). In an embodiment, the moving mechanism may be controlled remotely using a handheld device (not shown) comprising one of wifi, Bluetooth and like functions. Specifically in an embodiment, the movement of plurality light emitting diodes 118 in order to adjust beam angle of light may be controlled remotely by a handheld device comprising one of wifi, Bluetooth and like functions. For controlling such movement remotely, the bulb 100 may comprise a motor (not shown) placed at the bottom of the base 102 of the bulb 100.

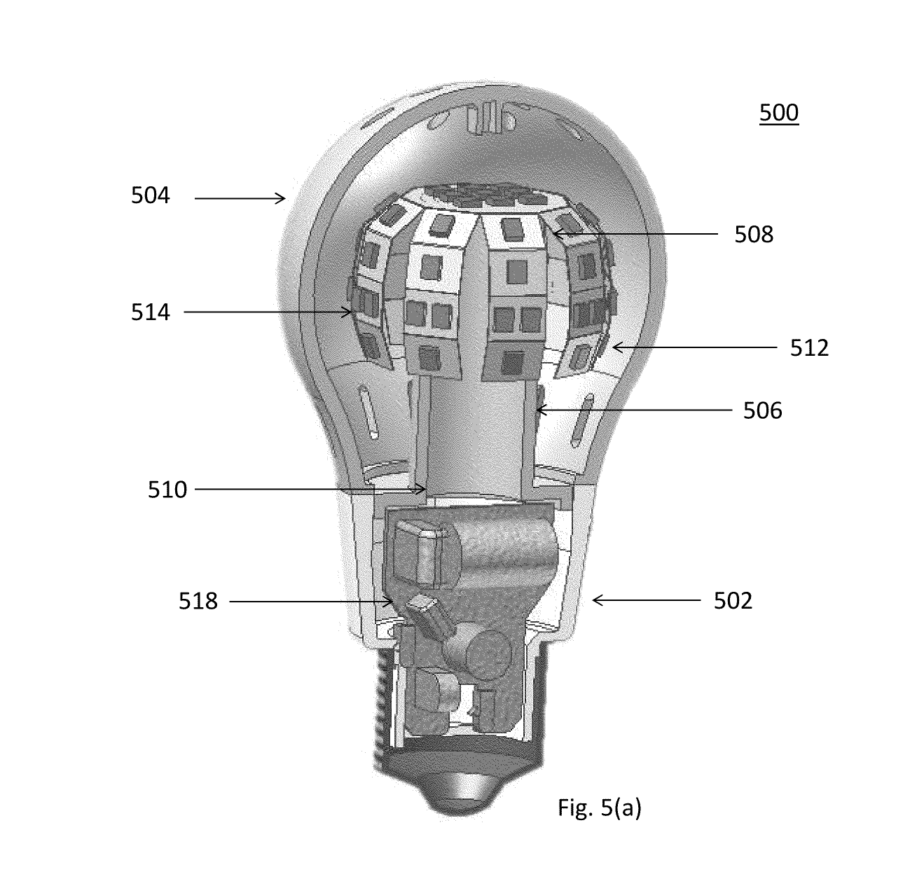

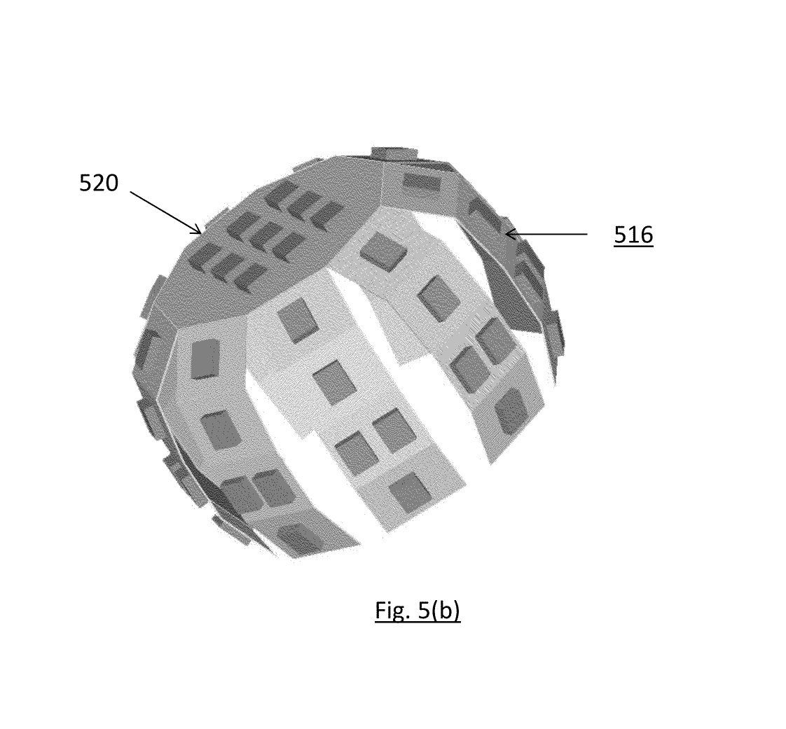

FIG. 5(a) shows front view of a light emitting diode bulb 500. The bulb 500 may be used for adjustable dispersal of light. The bulb 500 comprising a base 502, an envelope 504 coupled to the base 502. The envelope 504 of the bulb 500 may be composed of one of glass, polymer and like material, wherein the material of the envelope 504 may be transparent for scattering of light from the bulb 500. The bulb 500 further comprise a mounting assembly 506 placed inside the envelope 504, wherein the mounting assembly 506 having a top surface 508 and a bottom surface 510. The top surface 508 of the mounting assembly 506 may be kept free and the bottom surface 510 of the mounting assembly 506 may remain fixed to the base 502. The said top surface 508 may be configured to mount a plurality of metal core printed circuit board (MCPCB) 512. The pluralities of metal core printed circuit board (MCPCB) 512 include a plurality of light emitting diode 514 mounted equidistance from each other. The metal core printed circuit board (MCPCB) 512 may comprise a plurality of arms 516 as shown in FIG. 5(b), wherein said arms 516 may be configured to include equal no of light emitting diodes 514 arranged equidistance from each other. All these pluralities of light emitting diode 514 may be connected to a control circuitry 518, secured within the base 502, through a set of wires (not shown). Further, the control circuitry 518 may be configured to regulate the plurality of light emitting diodes 514 so that the beam angle of light may be controlled. As shown in FIG. 5(b) the metal core printed circuit board (MCPCB) 512 may not only comprise light emitting diodes 514 mounted over the arms 516 but also over a top surface 520.

In an aspect, the control circuit 518 of the bulb 500 may be configured to regulate at least one of switching and brightness of light emitting diodes 514 mounted on metal core printed circuit board (MCPCB) 512. Further, the switching and brightness of the light emitting diode 514 may be controlled remotely via a handheld device (not shown), comprising one of wifi, Bluetooth and like features. In another aspect, the control circuit 518 may be configured to regulate at least one of the switching and brightness of the plurality of light emitting diode for at least one of the metal core printed circuit board (MCPCB) 512. Specifically, the control circuit 518 may control switching and brightness at least one of the arm 516 of any of the metal core printed circuit board (MCPCB) 512. In an embodiment, the bulb 500 may include an external knob (not shown), connected to the control circuit, wherein, the knob may be used to regulate the control circuit.

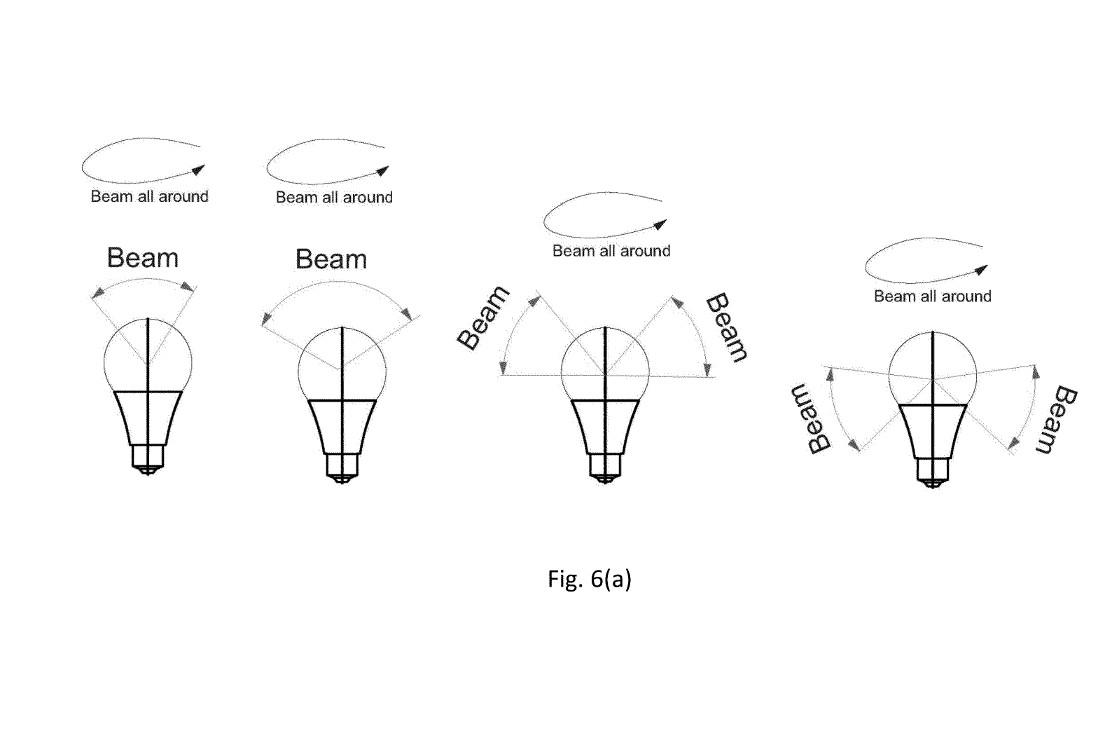

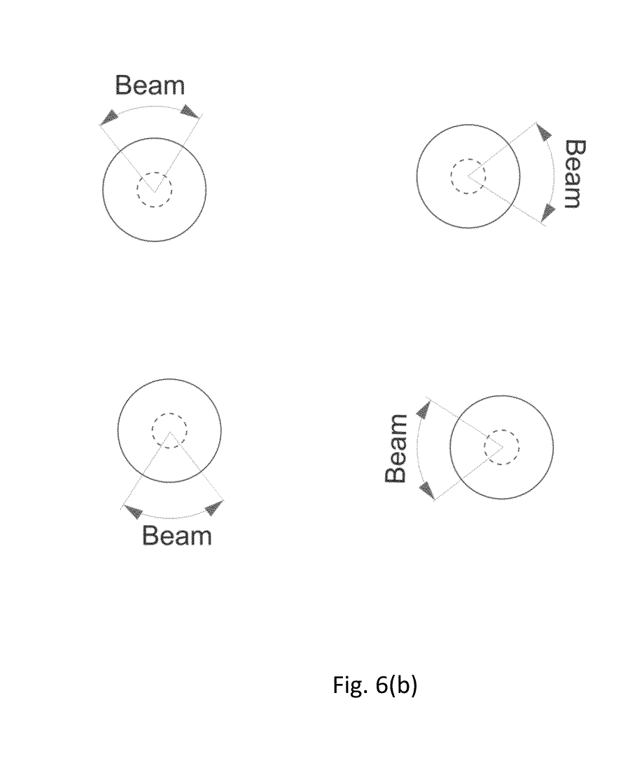

FIG. 6(a) depicts images of the light emitting bulb 100 with variable beam angle, showing scattering of light. FIGS. 6(a) clearly indicates that the said bulb may provide light at different beam angles, wherein the beam angle of the light coming out of the bulb may be controlled by the user. The user may rotate the knob 132 manually to move the plurality of light emitting diodes around their axis so that the beam angle of the light may be adjusted as per the user requirement. Moreover, FIG. 6(b) shows images of the light emitting bulb 500. As shown in FIG. 6(b) the direction of light from the bulb 500 may be adjusted by controlling the switching and brightness of at least one of the light emitting diode 514 of at least one of the arms 516 of the metal core printed circuit board (MCPCB) 512.

We claim:

1. A light bulb for adjustable dispersal of light, the bulb comprising:
a base;
an envelope coupled to the base;
a mounting assembly placed inside the envelope, the mounting assembly comprises a top surface and a bottom surface, wherein the bottom surface being fixed to the base;
a plurality of plate radially engaged over the top surface of the mounting assembly via hinge mechanism, using a plurality of hook, wherein the plurality of hook consist of a pinion formed around an outer periphery of the hook;
a plurality of light emitting diode (LED) mounted on top surface of the plurality of plates;
a connector arranged within the mounting assembly such that the connector extends longitudinally from the top surface to the bottom surface of the mounting assembly, the connector further comprising;
a plurality of rack attached radially to the connector such that each of the rack meshes with the respective pinion of the hook; and
a proximal end engaged to;
a cylindrical shaft having spiral grooves, such that the rotation of shaft allows the connector to move in one of upward and downward direction, wherein the said movement of the connector allows the pinion to move over the rack and thus actuating the movement of the plurality of plates around their axis, via hinge mechanism in order to adjust beam angle of light.

2. The bulb as claimed in claim 1, wherein the proximal end of the connector is engaged within the spiral grooves of the cylindrical shaft such that the rotation of shaft provides linear motion to the connector.

3. The bulb as claimed in claim 1, wherein the cylindrical shaft is rotated via an external knob placed at the top of the envelope.

4. The bulb as claimed in claim 1, wherein the cylindrical shaft is rotated via the envelope.

5. The bulb as claimed in claim 4, wherein the cylindrical shaft is attached with the envelope forming a groove inside the envelope.

6. The bulb as claimed in claim 1, wherein the cylindrical shaft is rotated using a circular disc being attached to the shaft and is mounted over the top surface of the envelope.

7. The bulb as claimed in claim 1, wherein the rotation of shaft allows the user to move the plurality of light emitting diodes simultaneously in one direction to adjust the beam angle of the light from the bulb.

8. The bulb as claimed in claim 1, wherein the movement of plurality of light emitting diodes is performed remotely by a handheld device comprising one of wifi, bluetooth and like functions.

9. A light bulb with adjustable dispersal of light, the bulb comprising:
a base;
an envelope coupled to the base;
a mounting assembly placed inside the envelope, the mounting assembly comprises a top surface and a bottom surface, wherein the bottom surface is fixed to the base;
a plurality of metal core printed circuit board (MCPCB) mounted radially over the top surface of the mounting assembly, wherein the plurality of metal core printed circuit board comprising;
a plurality of light emitting diodes placed equidistance to each other; and
a control circuit secured within the base, wherein the control circuit is configured to regulate the plurality of the light emitting diodes in order to adjust beam angle of light.

10. The bulb as claimed in claim 9, wherein the mounting assembly comprises plurality of pre-shaped metal core printed circuit board mounted radially over the top surface.

11. The bulb as claimed in claim 9, wherein the plurality of metal core printed circuit board comprise equal no of light emitting diode arranged equidistance from each other.

12. The bulb as claimed in claim 9, wherein the control circuit is configured to control at least one of switching and brightness of light emitting diodes.

13. The bulb as claimed in claim 12, wherein the control circuit is attached to an external knob, wherein the knob is configured to regulate the control circuit.

14. The bulb as claimed in claim 12, wherein the switching and brightness of light emitting diode is controlled remotely by a handheld device comprising one of wifi, bluetooth and like functions.

15. The bulb as claimed in claim 12, wherein the control circuit is configured to control at least one of the switching and brightness of the plurality of light emitting diode of at least one of the metal core printed circuit board.

16. A method for adjusting the scattering of light from the bulb, the method comprising:
rotating a knob, manually to move the plurality of light emitting diodes around their axis, so that the beam angle of the light from the bulb is adjusted.

17. The method as claimed in claim 16, wherein the beam angle is adjusted by controlling at least one of switching and brightness of light emitting diodes in the bulb.

18. The method as claimed in claim 16, wherein the movement of light emitting diodes is controlled remotely by a handheld device comprising one of wifi, bluetooth and like features.
